(19) United States
(12) Patent Application Publication
(10) Pub. No.: US 2017/0072491 A1
(43) Pub. Date: Mar. 16, 2017

(54) Soldering Device Minimizing Voids When Soldering Printed Circuit Boards

(71) Applicant: ERSA GmbH, Wertheim (DE)

(72) Inventor: Viktoria Rawinski, Marktheidenfeld (DE)

(21) Appl. No.: 15/341,487

(22) Filed: Nov. 2, 2016

Related U.S. Application Data
(62) Division of application No. 14/531,860, filed on Nov. 3, 2014.

(30) Foreign Application Priority Data
Nov. 11, 2013 (DE) 10 2013 112 367.8
Sep. 26, 2014 (EP) 14 186 548.5

(51) Int. Cl. B23K 1/00; H05K 3/34; B23K 1/008; B23K 1/06; B23K 3/04; B23K 3/08

(52) U.S. Cl. CPC B23K 1/0016; B23K 3/04; B23K 3/08; B23K 1/008; B23K 1/06; H05K 3/341; H05K 2203/0292; H05K 2203/1509

(57) ABSTRACT

A soldering device for soldering a printed circuit board includes at least one heating appliance melting solder situated between electrical or electronic components being soldered onto a printed circuit board and the printed circuit board. At least one actuator mechanically oscillates the printed circuit board at a variable frequency of oscillation in a direction of a plane defioned by the printed circuit board. A second lateral edge of the printed circuit board, the second lateral edge being opposite to the first lateral edge of the printed circuit board, rests against iand supported by a fixed stop.

### CROSS REFERENCE TO RELATED APPLICATION

This application is a divisional application of U.S. patent application Ser. No. 14/531,860 filed on Nov. 3, 2014 which claims the priority benefit of German Patent Application No. 10 2013 112 367.8 filed on Nov. 11, 2013 and European Patent Application No. 14 186 548.5 filed on Sep. 26, 2014, all of which are fully incorporated herein by reference.

### STATEMENT REGARDING FEDERALLY SPONSORED RESEARCH OR DEVELOPMENT

Not applicable.

### FIELD OF THE INVENTION

The invention relates to a method for minimizing voids when soldering printed circuit boards.

### BACKGROUND OF THE INVENTION

Various methods as well as soldering devices for soldering printed circuit boards being equipped with electrical and/or electronic components are known from the state of the art, wherein a solid-state solder is arranged between the printed circuit board and the relevant component, in particular in the case of components being arranged on the surface area of the printed circuit board, and, even more particularly, in the case of so-called SMDs. By means of an appropriate heating appliance, the solder is initially melted in a soldering installation and is subsequently cooled again, resulting, when the solder solidifies, in a mechanical connection that is electrically conductive between the printed circuit board and the component.

In these known soldering methods, it is disadvantageous that inclusions are habitually formed in the solder between the component and the printed circuit board. The extent to which these so-called voids, which are normally gaseous, are formed crucially depends on which solder paste is selected, on the printed circuit board substrate and on the soldering parameters. In this respect, causes of said voids are normally the flux being employed in the solder, paste, the solder resist used and volatile elements of the printed circuit board substrate. Depending on how many occurrences of voids there are and on the dimensions and the position the same have, said voids can lead to failure of the soldering point and/or the components, which may lead to inadmissible field failures, especially in the area of power electronics and in high-end industries like the aerospace industry.

In order to avoid such voids or to diminish them at the very least, soldering in a pressure chamber under negative pressure or under excess pressure is known. When soldering under negative pressure, there is, however, in particular the risk that inclusions of water in the molecular chains or in microclearances of the plastic housings of the components and of the printed circuit board substrate, said microclearances being situated between the molecular chains, pass into the vapor phase and try to escape. This may lead to the plastic housings of the components being destroyed and to the printed circuit boards being delaminated. When soldering under excess pressure, the voids are not removed; rather they are only compressed and reduced in size, so that, in future alternating temperature loads of the soldering connections, said connections are subjected to a high mechanical load, which may lead to the soldering connections being destroyed.

From document 10 2004 036 521 B4, a method for producing a soldering connection is furthermore known, in which method gas inclusions in the solder are supposed to be diminished or driven out in that two soldering partners are oscillated using a vibrator, molten solder being arranged between said two soldering partners. In this respect, the oscillation exciter introduces the oscillations substantially transversely to the component plane, so that the components, as to whole, are movie in the type of a vibrator. In this respect, it is in particular disadvantageous that this may lead to an undesirable dislocation in small and midget components and that, without an additional vacuum, the gas inclusions are insufficiently removed.

### SUMMARY OF THE INVENTION

Proceeding from this state of the art, it is consequently the object of the present invention to diminish the aforodescribed disadvantages and to minimize the formation of voids in the soldering points.

Before the method according to the present invention is carried out, the printed circuit board, for a start, is equipped with the components to be soldered on, wherein one solder deposit is arranged between the components and the printed board in each instance. After insertion into a soldering installation—this will normally be a soldering installation with at least one soldering chamber—, the solder is melted, in accordance with the invention, in said soldering installation by means of an arbitrary heating device. Throughout melting or afterwards, that is to say after the solder has already entirely been melted, a mechanical oscillation is applied to the printed circuit board. In this respect, the frequency of the oscillation changes between a starting frequency and a final frequency.

In contrast to the methods that are known from the state of the art, the oscillation is introduced in a direction of the printed circuit board plane by directly or indirectly coupling at least one actuator to at least one lateral edge of the printed circuit board. In this respect, said printed circuit board, with its lateral edge that is opposite to the actuator in each instance, is supported at a dead stop in the type of an abutment.

In other words, this implies, for a start, that the oscillations are substantially introduced into the printed circuit board as longitudinal waves referring to the printed circuit board plane. By means of the mutually opposite arrangement, again referring to the printed circuit board, of the actuator and of the dead stop, the printed circuit board ergo is not vibrated, but the printed circuit board substrate is rather compressed and decompressed in quick succession. In this respect, the frequency of the actuator changes between a starting frequency and a final frequency while the solder is in a molten state. The oscillations of the printed circuit board are directly transmitted onto the molten solder and also onto the components that are arranged above the same, being dampened by the molten solder. By means of the kinetic energy that is transmitted into the solder by means of the printed circuit board that oscillates, in particular gaseous inclusions—voids—are entirely or, at the very least, partially driven out of the solder. By means of this measure, the voids are diminished as a whole.

This also considerably favors the thermal transition between the component and the printed circuit board, which transition represents a substantial power factor, in particular in high power electronics.

In accordance with the invention, the actuator can directly come to rest against a lateral edge of the printed circuit board, or else indirectly, that is to say in particular via a printed circuit board frame, on which the printed circuit board is held throughout the soldering process, or via a transport device, when the printed circuit board is moved on said transport device through the soldering installation throughout the soldering process. For the dead stop, it is necessary that the same is arranged in a fixed position with respect to the printed circuit board, so that the latter can be supported at the same. In this respect, said dead stop can both be arranged in a fixed position in the soldering installation and can be taken to its stop position before the actuator is activated. It is similarly conceivable, while the printed circuit board is transported through the soldering installation, that the dead stop as well as the actuator are moved through the soldering installation together with the printed circuit board.

According to an exemplary embodiment of the invention that is particularly preferred, the frequency is raised between the starting frequency and the final frequency step by step or constantly in the type of a sweep. In this respect, said raising can be linear, stepwise or logarithmic. An oscillation that is sweep-like in such a way ensures, in this respect, that a plurality of natural frequencies are excited, which leads to a particularly effective transmission of the oscillation from the printed circuit board to the molten solder, and thus to a particularly effective minimizing if voids. Additionally, with an increasing frequency, the modulus of elasticity of the printed circuit board material is raised and the printed circuit board is thus stiffened, resulting in the energy transmission onto the liquid solder likewise being raised.

In order to ensure, in the substrate of the printed circuit board, a gentle propagation of the oscillations that is as homogeneous as possible, provision is made, according to a further exemplary embodiment, for selecting the starting frequency to be as low as possible. The target frequency preferably is to be selected so that as many natural frequencies as possible, under ideal circumstances all of the natural frequencies of the printed circuit board, are comprised. In a frequency range between 0 Hz and 15 kHz for exciting the printed circuit board, these requirements have been shown to be fulfilled almost ideally for most of the printed circuit board geometries and sizes. It is particularly advantageous to begin with a starting frequency between 0 Hz and 10 Hz and to increase said frequency up to the final frequency between 1 kHz and 15 kHz. Thus, with one sweep, the whole resonance spectrum of almost any printed circuit board can be excited independently of the geometry thereof and of the components that are arranged thereon, so that no specific settings need to be adjusted for different sizes of printed circuit boards, resulting in set-up times being reduced and in the possibility to spare complex control appliances.

The mode of the oscillation for exciting the printed circuit board is initially irrelevant. However, it has proven to be particularly advantageous if the oscillation is embodied to be sinusoidal.

In a basically arbitrary manner, the waveform between the starting frequency and the final frequency can be embodied as a single cycle, which extends, at the very least, over a portion of the time period in which the solder is molten. According to a farther embodiment of the invention at the very least two cycles are, however, carried out one after the other. This implies that after the final frequency has been reached in one cycle, the subsequent cycle begins with the starting frequency again. In this respect, the cycles can be identical or different in respect of the starting frequency and the final frequency.

Here, it has shown to be advantageous to make the duration of a cycle vary from 0.1 sec to 10 sec while the duration of all of the cycles per printed circuit board together varies from 10 sec to 120 sec. Selecting, a cycle with a duration between 1 sec and 5 sec is particularly advantageous, wherein the oscillation is applied, as a whole, over a period of 10 sec to 60 sec.

The embodiment with short cycles with multiple repetitions has shown to be particularly effective for reducing the voids, whereas, in a single cycle or, in particular also with a constant oscillation excitation, it may happen that small voids accumulate to large void, which, in turn, makes escaping between the component and the printed circuit board more difficult.

Even though it has shown to be particularly advantageous to apply oscillations over a period of up to approximately 60 sec, it is similarly possible, for further reducing voids, to apply oscillations throughout the whole duration of the soldering process, that is to say while the solder temperature is above the liquidus temperature.

According to a further exemplary embodiment of the invention, the actuator indirectly or directly rests against the printed circuit board before the beginning of the oscillation cycle, with a low prestress at the very least. This ensures that, throughout the whole oscillation cycle, the printed circuit board is subject to a low compressive stress at the very least.

Basically any height can be chosen for the oscillation amplitude, as long as, on the one hand, voids are sufficiently minimized and, on the other hand, mechanical damage to the printed circuit board is reliably precluded. Amplitudes between 10 μm and 200 μm, in particular between 50 μm it and 100 μm, have proven to be particularly advantageous.

The soldering device in accordance with the invention for soldering a printed circuit board being equipped with electrical or electronic components, which printed circuit board is suitable for carrying out the method being described hereinbefore, initially features at least one soldering area, at least one heating appliance being arranged in the soldering area for melting the solder being situated between the components and the printed circuit board, at least one actuator for introducing mechanical oscillations into the printed circuit board and a control appliance for changing the frequency of the oscillations of the actuator. In this respect, the soldering area can, for instance in a rework soldering station, be embodied as an open area in the type of a soldering rack or else, for instance in a reflow soldering installation, it can be embodied as a soldering or process chamber.

In accordance with the invention, the actuator is embodied and arranged so that, in the area of at least one first lateral edge of the printed circuit board, it can indirectly or directly come to rest against said printed circuit board in such a manner that an oscillation can be introduced into the printed circuit board in a direction of the printed circuit board plane. Furthermore, provision is made for an abutment-like dead stop, against which a second lateral edge of the printed circuit board, the second lateral edge being opposite to the first lateral edge of the printed circuit board, can come to rest, in a way being supported.

Basically any type of actuator or oscillation generator can be chosen; according to an exemplary embodiment of the invention, the actuator, however, features a piezoelectric transducer, in particular a piezoelectric stack transducer, a piezoelectric fiber transducer or a piezoelectric ceramic transducer.

Alternatively, the actuator can feature a magnetostrictive transducer, a transducer being made from a magnetic shape memory alloy and/or an electromagnetic oscillation coil.

According to a further embodiment of the invention, provision is made for a transport device for transporting the printed circuit board into the soldering area, through the soldering area and out of the soldering area, in particular in the case of a soldering chamber. In this respect, the actuator and/or the dead stop can be stationarily arranged in the soldering area or in the soldering chamber. Preferably, however, the actuator and/or the dead stop can be moved in the transport direction together with the primed circuit board or at the very least synchronously with the same. By means of this measure, in a simple manner, constant operation of the soldering installation can be ensured.

Provision can further be made for a transport frame or a printed circuit board frame for receiving the printed circuit board throughout transporting and/or throughout the soldering process. In this respect, the actuator can directly be coupled to the printed circuit board by paeans of direct contact, or else it can indirectly be coupled to the printed circuit board via the transport device, via the transport frame or the printed circuit board frame.

The printed circuit board can also indirectly be supported at the dead stop via the transport device, via the transport frame or the printed circuit board frame, or the dead stop can be formed by the transport frame or the printed circuit board frame.

### BRIEF DESCRIPTION OF THE DRAWINGS

The following description explains the invention in greater detail with the help of drawings only showing examples, in the figures:

FIG. 1 shows a first exempla embodiment of an arrangement of a printed circuit board being equipped with components with an oscillation generator in cross-section;

FIG. 2 shows a second exemplary embodiment of an arrangement of a printed circuit board being equipped with components with an oscillation generator in cross-section along sectional line

### A-A in FIG. 3;

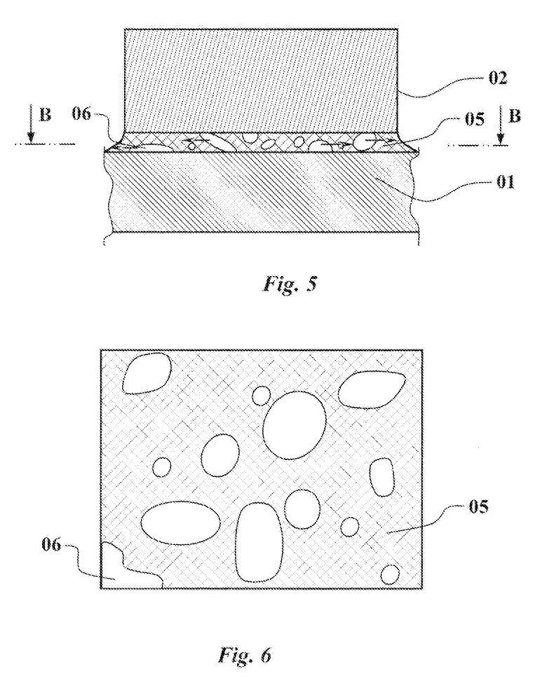

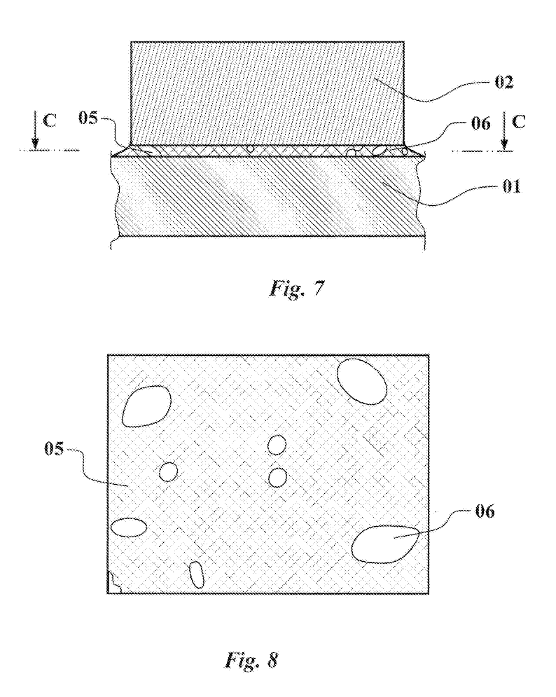

FIG. 3 shows the exemplary embodiment according to FIG. 2 in a view from above;

FIG. 4 shows a third exemplary embodiment of an arrangement of a printed circuit board being equipped with components with an oscillation generator in as view from above that corresponds to FIG. 3;

FIG. 5 shows, in a schematic illustration in cross-section, the soldering connection between a component and the printed circuit board with voids being present;

FIG. 6 shows, in a section along sectional line B-B in FIG. 5, a typical distribution of voids in the soldering connection:

FIG. 7 shows, in an illustration that corresponds to FIG. 5, the soldering connection between a component and the printed circuit board with voids that have been reduced in accordance with the invention; and

FIG. 8 shows, in an illustration that corresponds to FIG. 6, along sectional line C-C in FIG. 7, the soldering connection with voids that have been reduced in accordance with the invention.

### DETAILED DESCRIPTION OF THE EXAMPLE EMBODIMENT

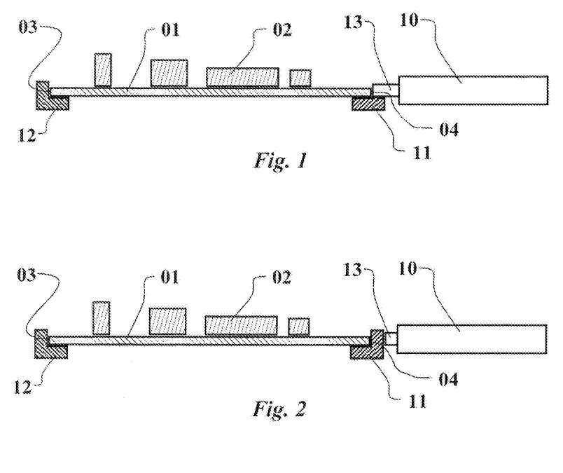

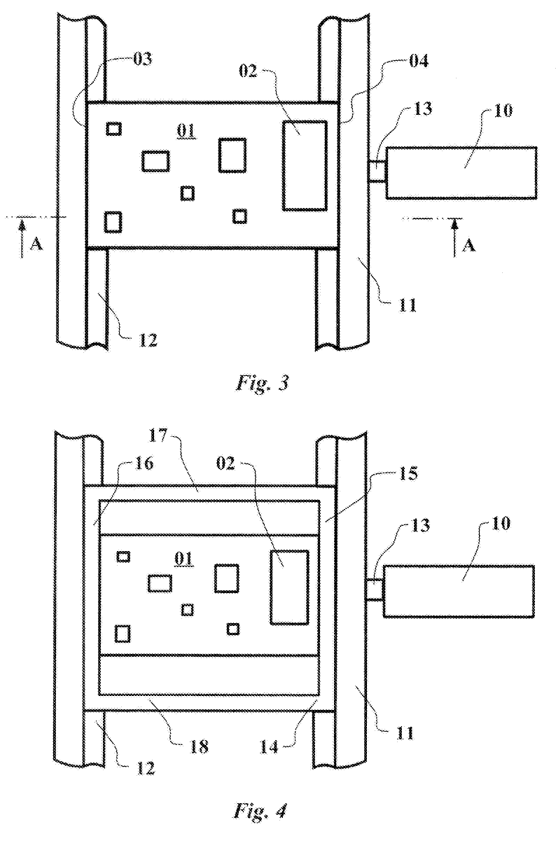

In FIG. 1, in a first exemplary embodiment, the arrangement of an oscillation generator or actuator 10 for exciting oscillations in as printed circuit board 01 is schematically illustrated. For reasons of a simpler and clearer illustration, the soldering installation in which the arrangement of the printed circuit board and of the actuator is arranged is not illustrated.

The printed circuit board 01 being equipped with electronic components 02 rests on a pair of carriers 11 and 12. In this respect, the carrier 12 is embodied as an angle that is L-shaped in cross-section, against the vertical leg of which a longitudinal edge 03 of the printed circuit board comes to rest. The carrier 12 is substantially rigidly fixed to a machine rack or to a housing of the soldering installation in a manner that is not illustrated and in this way forms a dead stop for the printed circuit board 01. The carrier 11 that is opposite to the carrier 12 only forms a rest for the lateral edge 04 of the printed circuit board 01 that is opposite to the lateral edge 03, so that said lateral edge 04 is arranged on the carrier 11 in the type of a floating bearing.

With its oscillator 13, the actuator 10 is directly coupled to the longitudinal edge 04 of the printed circuit board 01, that is to say it has come to rest against the same. In this respect, said resting can he effected under a low prestress at the very least.

If the actuator 10 is now excited to oscillate via a control appliance that is not illustrated, the oscillator 13 compresses and decompresses the printed circuit board 01 in quick succession between the actuator 10 and the carrier 12 acting as a dead stop.

In the exemplary embodiment of the invention that is illustrated in FIGS. 2 and 3, the two carriers 11 and 12 form a part of a transport device for transporting into or through the soldering chamber or into or through the sol den 11 area of a soldering installation that is not illustrated. The carrier 12, in turn, forms a dead stop for the longitudinal edge 03 of the printed circuit board 01 with its vertical leg. In contrast to the exemplary embodiment that is illustrated in FIG. 1, the carrier 11 is also embodied as an angle that is L-shaped in cross-section, against the vertical leg of which the longitudinal edge 04 of the printed circuit board that is opposite to the longitudinal edge 03 comes to rest. In this respect, the printed circuit board can he held between the vertical legs of the carriers 11 and 12 under a low prestress at the very least.

The oscillator 13 of the actuator 10 rests, possibly under a prestress, against the vertical leg of the carrier 12 and thus indirectly against the longitudinal edge 04 of the printed circuit board 01. If the actuator is now excited to oscillate by means of the control appliance, the oscillation is indirectly transmitted onto the printed circuit board, either due to an elastic deformability of the carrier 11, or due to an at least marginal movabililty of the carrier 11 relative to the carrier 12, resulting in the printed circuit board in turn being compressed and decompressed in quick succession.

The exemplary embodiment that is illustrated in FIG. 4 corresponds, in its basic structure, to the exemplary embodiment according to FIGS. 2 and 3. In contrast to the previous exemplary embodiment, in which the printed circuit board 01 directly rests on the carriers 11 and 12 of the transport device, in the exemplary embodiment according to FIG. 4, the printed circuit board 01 is arranged in a soldering frame 14. In said soldering frame, the printed circuit board, while being transported through the soldering device or through the soldering installation, is held or supported at the carriers 11 and 12. In this respect, the soldering frame features two transverse struts 15 and 16 as well as two longitudinal struts 17 and 18. In this respect, the soldering frame 14 has to be designed and dimensioned so that, when indirectly introducing oscillations into the printed circuit board 01 via the carrier 11 and via the transverse struts 15 by means of the actuator 10, a deformability that is in particular elastic, at the very least of the longitudinal struts 17 and 18, can be effected by means of compression and/or bending, so that the printed circuit board, in accordance with the invention, can be compressed and decompressed in quick succession.

At the beginning of the oscillation excitation, a plurality of voids 06 in the form of gaseous inclusions is situated—as FIG. 5 outlines by way of example—in the solder 05 between the component 02 and the printed circuit board 01, the voids accounting for a substantial part of the surface—see the soldering connection in FIG. 6 that is outlined by way of example concerning the printed circuit board plane.

Due to the oscillation excitation of the printed circuit board 01, as is explained hereinbefore, a movement of the voids 06 in the liquid solder 05 is caused, said voids being driven out of the molten solder 05 when the edge of the connection between the component 02 and the printed circuit board 01 is reached. This results in the number of voids 06 in the solder 05 being significantly reduced after the oscillation excitation has been carried out—as FIGS. 7 and 8 outline by of example. Hereby, a considerably improved quality of the soldering connection between the components 02 and the printed circuit board 01 is ensured.

1. A soldering device for soldering a printed circuit board, said device comprising:
at least one heating appliance heating molten solder situated between electrical or electronic components being soldered onto a printed circuit board and the printed circuit board;
at least one actuator mechanically oscillating the printed circuit board at a frequency of oscillation, wherein the actuator, in an area of a first lateral edge of the printed circuit board, indirectly or directly comes to rest against said printed circuit board in such a manner that an oscillation is introduced into the printed circuit board substantially parallel to a plane defined by the printed circuit board, said frequency of oscillation changing between a start frequency and an end frequency; and
a fixed stop acting in a manner of a thrust bearing rests against and supports a second lateral edge of the printed circuit board, the second lateral edge being opposite to the first lateral edge of the printed circuit board.

2. The soldering device according to claim 1, in which the actuator includes a piezoelectric transducer.

3. The soldering device according to claim 1, in which the actuator includes a magnetostrictive transducer, a transducer being made from a magnetic shape memory alloy and/or an electromagnetic oscillation coil.

4. The soldering device according to claim 1, in which the soldering device is a rest soldering device or a rework soldering station.

5. The soldering device according to claim 1, including a transport device transporting the printed circuit board into a soldering area of the soldering device, through the soldering area, and out of the soldering area, wherein the actuator and the dead stop can be moved in the transport direction together with the printed circuit board or at the very least synchronously with the same.

6. The soldering device according to claim 5, including a transport frame or a printed circuit board frame receiving the printed circuit board.

7. The soldering device according to claim 6, in which the actuator is indirectly coupled to the printed circuit board via the transport device, via the transport frame or the printed circuit board frame.

8. The soldering deice according to claim 6, in which the printed circuit board is indirectly supported at the dead stop via the transport device, via the transport frame or the printed circuit board frame, or wherein the dead stop is formed by the transport frame or the printed circuit board frame.
